(19) United States
(12) Patent Application Publication
(10) Pub. No.: US 2013/0093554 A1
(43) Pub. Date: Apr. 18, 2013

(54) METHOD AND APPARATUS FOR REDUCING PRESSURE EFFECTS ON AN ENCAPSULATED DEVICE

(71) Applicant: Enphase Energy, Inc., Petaluma, CA (US)

(72) Inventors: Martin Fornage, Petaluma, CA (US); Raghuveer R. Belur, Los Altos Hills, CA (US)

(73) Assignee: Enphase Energy, Inc., Petaluma, CA (US)

(21) Appl. No.: 13/649,802

(22) Filed: Oct. 11, 2012

Related U.S. Application Data
(60) Provisional application No. 61/547,451, filed on Oct. 14, 2011.

(51) Int. Cl. H05K 5/02; H01F 27/06; H05K 13/00; H05K 5/04

(52) U.S. Cl. 336/65; 361/728; 361/746; 29/592.1

(57) ABSTRACT

A method and apparatus for reducing pressure effects on an encapsulated device. In one embodiment, the apparatus comprises a power module comprising an equipment box assembly containing (i) an equipment module housing, (ii) a potted electronic device disposed within the equipment module housing, and (iii) a resilient expansion absorption layer disposed between at least a portion of the potted electronic device and at least a portion of the equipment module housing.

### CROSS-REFERENCE TO RELATED APPLICATIONS

This application claims benefit of U.S. provisional patent application Ser. No. 61/547,451, filed Oct. 14, 2011, which is herein incorporated in its entirety by reference.

### BACKGROUND OF THE INVENTION

1. Field of the Invention

Embodiments of the present disclosure relate generally to electronic device, and more particularly, to a method and apparatus for reducing the effects of pressure on encapsulated electronic devices.

2. Description of the Related Art

Certain electronic devices may require encapsulation, or potting, to prevent exposure to corrosive elements such as moisture, salt, acid, and the like. For example, electronic devices utilized in systems for generating energy from renewable resources, such as solar power systems, wind farms, hydroelectric systems, or the like, may be exposed to environment elements and therefore require encapsulation. Such electronic devices may include printed circuit (PC) boards comprising electronic components used in inverters, converters, power supplies, and the like.

Although encapsulating electronic devices within equipment module housings protects the devices and corresponding components from contact with corrosive elements, such encapsulation may subject the electronic devices/components to stress from compression. For example, thermal changes such as increase in temperature may result in an expansion of the encapsulating material that is greater than an expansion of the equipment module housing, resulting in a potentially damaging increase in pressure on the electronic device/components. Certain electronic components, such as ferrite transformers, may be particularly susceptible to negative effects from such stress and may suffer damage such as cracking.

Therefore, there is a need in the art for a method and apparatus for reducing pressure effects on encapsulated devices.

### SUMMARY OF THE INVENTION

Embodiments of the present invention generally relate to a method and apparatus for reducing pressure effects on an encapsulated device. In one embodiment, the apparatus comprises a power module comprising an equipment box assembly containing (i) an equipment module housing, (ii) a potted electronic device disposed within the equipment module housing, and (iii) a resilient expansion absorption layer disposed between at least a portion of the potted electronic device and at least a portion of the equipment module housing.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a perspective, exploded view of an assembly for reducing pressure effects on an encapsulated device in accordance with some embodiments of the present invention;

FIG. 2 is a cross-sectional view of an equipment box assembly taken along line 2-2 of FIG. 1 in accordance with one or more embodiments of the present invention;

FIG. 3 is a flow diagram of a method for reducing pressure effects on an encapsulated device in accordance with one or more embodiments of the present invention; and

FIG. 4 is a block diagram of a system for generating power in accordance with one or more embodiments of the present invention.

### DETAILED DESCRIPTION

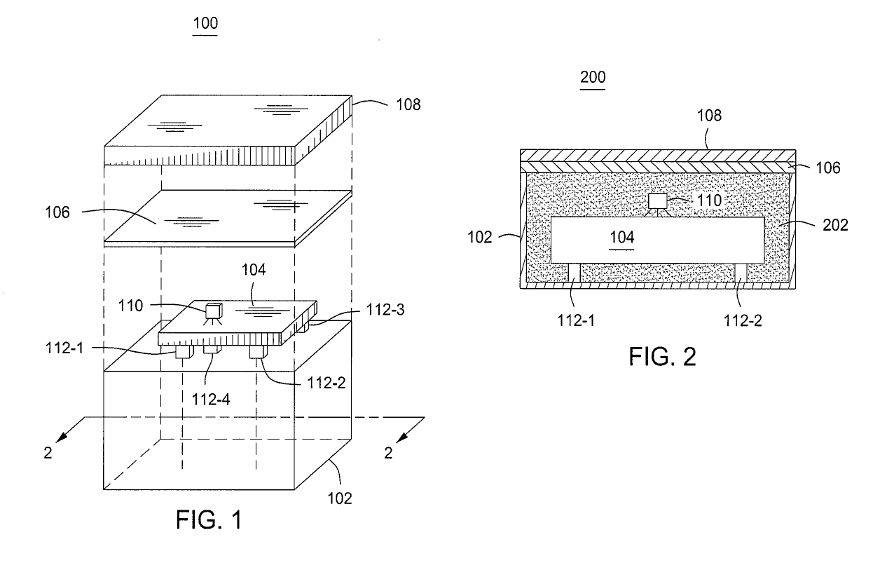

FIG. 1 depicts a perspective, exploded view of an assembly 100 for reducing pressure effects on an encapsulated device in accordance with some embodiments of the present invention. The assembly 100 includes an equipment box 102 having an electronic device 104 disposed therein and an equipment box lid 108 (referred to as “lid 108”) disposed atop the equipment box 102; generally, the lid 108 is considered to be part of the equipment box 102.

The equipment box 102, for example an equipment module housing, is a suitably sized and shaped enclosure for encasing the electronic device 104. The equipment box 102 may be formed from any rigid material such as metal, plastic, or a combination thereof. In some embodiments the equipment box 102 may be a die-cast metal box, for example aluminum, zinc, or other metal alloys, with limited to no flexibility or expansion capability.

The electronic device 104 may be any electronic device, for example a device that requires enclosure to protect the device from potentially corrosive elements, such as moisture, air, salt, acid, or the like. Exemplary electronic devices 104 may be, but are not limited to, printed circuit (PC) boards that are used in power modules (e.g., DC/AC or AC/DC inverters, converters, power supplies, or the like) or any type of electronic module. The electronic device 104 includes at least one electronic component 110, such as a capacitor, resistor, transistor, transformer, or the like, disposed, for example, on an upper surface of the electronic device 104. In some embodiments, the electronic component 110 is a ferrite transformer.

The electronic device 104 is disposed within the equipment box 102, for example along the interior bottom of the equipment box 102 as supported by supporting members 112-1, 112-2, 112-3, and 112-4.

The lid 108 may be disposed atop the equipment box 102 as illustrated in FIG. 1. The lid 108 may be formed from any rigid material, such as plastic or metal, and has a suitable size and shape to fit atop the equipment box 102. The lid 108 may be secured to the equipment box 102 by any suitable means including epoxy, screws, clips, fasteners, or the like.

During assembly, a suitable potting material (not shown) is introduced into the equipment box 102 for potting the electronic device 104/electronic component 110 to prevent contact with potentially damaging elements, such as moisture, salt, acid, and the like. Examples of such potting materials may include polyurethane, epoxy, silicone, and the like.

In accordance with one or more embodiments of the present invention, a resilient expansion absorption layer 106 is disposed between the potted electronic device 104 and the lid 108. The resilient expansion absorption layer 106 may be formed from any suitable material, such as closed-cell foam, capable of being compressed to absorb pressure within the equipment box 102 due to expansion of the potting material (e.g., during periods of increased temperatures). The resilient expansion absorption layer 106 generally has the same dimensions of width and length as the equipment box 102, with a thickness, for example, of 2-4 millimeter (mm). In some embodiments, the resilient expansion absorption layer 106 may be a sealed pliant casing containing one or more resilient elements, such as a sealed plastic bag partially filled with air.

The resilient expansion absorption layer 106 may be adhered to the inner surface of the lid 108 by an adhesive such as glue, VHB™ (Very High Bond) tape, or similar substance. In some embodiments, the resilient expansion absorption layer 106 may extend to the edges of the lid 108 such that the resilient expansion absorption layer 106 seals any gaps between the lid 108 and the equipment box 102/potting material when the lid 108 is secured atop the equipment box 102. In some alternative embodiments, rather than being disposed between the lid 108 and the equipment box 102/potting material, the resilient expansion absorption layer 106 may be disposed in an alternative location within the equipment box 102, for example between the bottom of the equipment box 102 and the potted electronic device 104. In other alternative embodiments, the resilient expansion absorption layer may be completely or substantially surround the potted electronic device 104.

In one or more other embodiments, the electronic component 110 may be potted within the equipment box 102 without the electronic device 104. For example, the equipment box 102 may be sized and shaped for encapsulating a single electronic component, such as a ferrite transformer, where leads for electrically coupling to the electronic component 110 extend through the equipment box 102.

FIG. 2 is a cross-sectional view of an equipment box assembly 200 taken along line 2-2 of FIG. 1 in accordance with one or more embodiments of the present invention. The equipment box assembly 200 comprises the equipment box 102 having disposed therein the electronic device 104. The electronic device 104 is supported along the inner floor of the equipment box 102 by support members 112-1 and 112-2, and comprises the electronic component 110. A potting material 202 is disposed within the equipment box 102 such that the electronic device 104, including the electronic component 110, is substantially encapsulated by the potting material 202. The potting material 202 may be any suitable material, such as polyurethane, epoxy, silicone, and the like, for protecting the electronic device 104 from contact with potentially damaging elements, such as air, moisture, salt, acid, and the like. The potting material 202 may be self-curing such that it hardens on its own following application, or the potting material 202 may be hardened by light, heat, or another suitable hardening means to form the potted assembly 200.

The lid 108 is disposed along the top of the equipment box 102. The resilient expansion absorption layer 106 is retained between the lid 108 and the potting material 202 such that the resilient expansion absorption layer 106 is generally in contact with the potting material 202. The resilient expansion absorption layer 106 may extend to the edges of the lid 108 such that any gaps between the lip 108 and the equipment box 102 are sealed. In some embodiments, the resilient expansion absorption layer 106 may be closed-cell foam having a thickness of 2-4 mm.

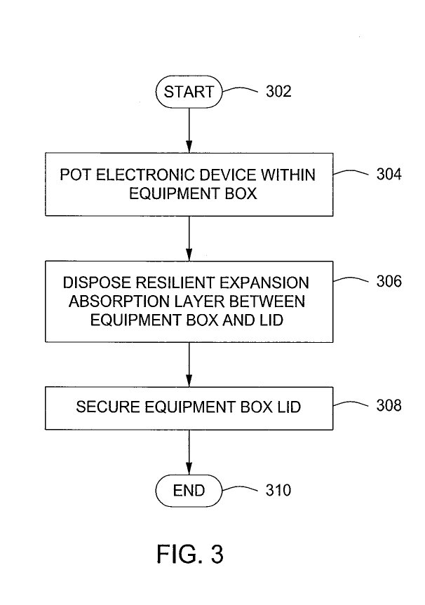

FIG. 3 is a flow diagram of a method 300 for reducing pressure effects on an encapsulated device in accordance with one or more embodiments of the present invention. The method 300 begins at step 302 and proceeds to step 304. At step 304, an electronic device comprising one or more electronic components, such as a printed circuit board comprising one or more of resistors, capacitors, transistors, transformers, and the like (e.g., electronic device 104 comprising electronic component 110), is encapsulated by potting material within an equipment box (e.g., equipment box 102). Exemplary electronic devices may be, but are not limited to, printed circuit (PC) boards that are used in inverters, converters, power supplies, and the like. In some embodiments, the electronic component may be potted within the equipment box without the electronic device; for example, the equipment box may be sized and shaped for encapsulating a single electronic component, such as a ferrite transformer, where leads for electrically coupling to the electronic component extend through the equipment box.

The equipment box may be formed from any rigid material such as metal, plastic, or a combination thereof. In some embodiments the equipment box may be a die-cast metal box, for example aluminum, zinc, or other metal alloys, with limited to no flexibility or expansion capability.

The method 300 proceeds to step 306, where a resilient expansion absorption layer (e.g., resilient expansion absorption layer 106) is disposed, for example, between the potted electronic device and a lid for the equipment box. The resilient expansion absorption layer may be formed from any suitable material, such as closed-cell foam, capable of being compressed to absorb pressure within the equipment box due to expansion of the potting material (e.g., during periods of increased temperatures). The resilient expansion absorption layer generally has the same dimensions of width and length as the equipment box, with a thickness, for example, of 2-4 millimeter (mm). In some embodiments, the resilient expansion absorption layer 106 may be a sealed pliant casing containing one or more resilient elements, such as a sealed plastic bag partially filled with air.

The resilient expansion absorption layer may be retained between the equipment box/potting material and the lid by being adhered to the inner surface of the lid by an adhesive such as glue, VHB™ tape, or similar substance. In some embodiments, the resilient expansion absorption layer may extend to the edges of the lid such that the resilient expansion absorption layer seals any gaps between the lid and the equipment box/potting material when the lid is secured atop the equipment box. In some alternative embodiments, rather than being disposed between the lid and the equipment box/potting material, the resilient expansion absorption layer may be disposed in an alternative location within the equipment box.

The method 300 proceeds to step 308, where the lid is secured atop the equipment box. The lid may be secured to the equipment box by any suitable means including epoxy, screws, clips, fasteners, or the like. The equipment box assembly may then be disposed within any equipment module as necessary, such as a power module (e.g., a DC/AC or AC/DC inverter, a converter, a power supply, or the like) or any type of electronic module requiring the potted electronic device. The method 300 proceeds to step 310 where it ends.

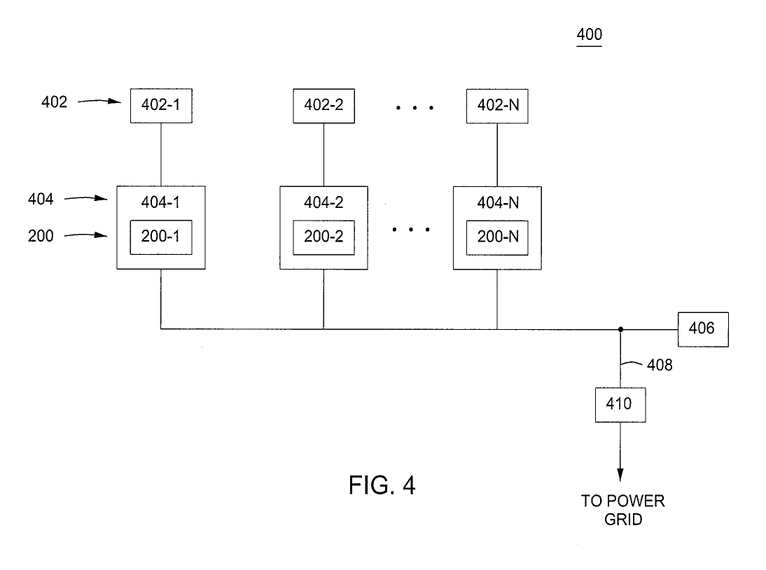

FIG. 4 is a block diagram of a system 400 for generating power in accordance with one or more embodiments of the present invention. This diagram only portrays one variation of the myriad of possible system configurations and devices that may utilize the present invention. The present invention can be utilized in any system or device requiring an equipment box assembly that comprises a potted device, such as DC/DC converters, DC/AC inverters, AC/DC inverters, or the like. In some embodiments, such as the embodiment described below, the system 400 comprises a plurality of DC/AC inverters for inverting DC power, received from solar photovoltaic (PV) modules, to AC power. Additionally or alternatively, the system may convert DC power from other DC power sources, such as other types of renewable energy sources (e.g., wind, hydroelectric, or the like), batteries, and the like. In other embodiments, the system 400 may comprise DC/DC converters, rather than DC/AC inverters, for converting the received solar energy to DC power.

The system 400 comprises a plurality of inverters 404-1, 404-2 . . . 404-N, collectively referred to as inverters 404; a plurality of PV modules 402-1, 402-2 . . . 402-N, collectively referred to as PV modules 402; a power conversion system controller 406; an AC bus 408; and a load center 410.

Each inverter 404-1, 404-2 . . . 404-N is coupled to a PV module 402-1, 402-2 . . . 402-N, respectively, in a one-to-one correspondence. The inverters 404 are further coupled to the power conversion system controller 406 via the AC bus 408. The power conversion system controller 406 is capable of communicating with the inverters 404 for providing operative control of the inverters 404. In some embodiments, the power conversion system controller 406 may be a monitor for monitoring the inverters 404; additionally or alternatively, the power conversion system controller 406 may be a networking hub for communicatively coupling the inverters 404 to the Internet. The inverters 404 are also coupled to the load center 410 via the AC bus 408.

The inverters 404 convert DC power generated by the PV modules 402 to commercial power grid compliant AC power and couple the AC power to the load center 410. The generated AC power may be further coupled from the load center 410 to the one or more appliances and/or to a commercial power grid. Additionally or alternatively, generated energy may be stored for later use; for example, the generated energy may be stored utilizing batteries, heated water, hydro pumping, H₂O-to-hydrogen conversion, or the like. In some embodiments, each inverter 404 may have a DC/DC converter coupled between the inverter 404 and the corresponding PV module 402. In some other embodiments, the PV modules 402 may all be coupled to a single inverter 404 for inverting the DC power to AC power (i.e., a centralized DC/AC inverter).

Each of the inverters 404 comprises an equipment box assembly 200 (i.e., the inverters 404-1, 404-2 . . . 404-N comprise the equipment box assemblies 200-1, 200-2 . . . 200-N, respectively). Each of the equipment box assemblies 200 comprises an equipment box having disposed therein a potted electronic device and a resilient expansion absorption layer retained between at least a portion of the equipment box (e.g., the lid of the equipment box) and the potting material as previously described (e.g., equipment box 102 with lid 108, electronic device 104, potting material 202, and resilient expansion absorption layer 106). Also as previously described, the electronic device includes at least one electronic component, such as a capacitor, resistor, transistor, transformer (e.g., a ferrite transformer), or the like. The resilient expansion absorption layer is capable of being compressed to absorb pressure within the equipment box due to expansion of the potting material, for example during periods of increased temperatures, thereby reducing the effects of such pressure on the potted electronic device.

The foregoing description of embodiments of the invention comprises a number of elements, devices, circuits and/or assemblies that perform various functions as described. These elements, devices, circuits, and/or assemblies are exemplary implementations of means for performing their respectively described functions.

While the foregoing is directed to embodiments of the present invention, other and further embodiments of the invention may be devised without departing from the basic scope thereof, and the scope thereof is determined by the claims that follow.

1. An apparatus for reducing pressure effects on an encapsulated device, comprising:
a power module comprising an equipment box assembly containing (i) an equipment module housing, (ii) a potted electronic device disposed within the equipment module housing, and (iii) a resilient expansion absorption layer disposed between at least a portion of the potted electronic device and at least a portion of the equipment module housing.

2. The apparatus of claim 1, wherein the electronic device is a printed circuit board.

3. The apparatus of claim 1, wherein the electronic device comprises at least one electronic component.

4. The apparatus of claim 3, wherein the at least one electronic component is a ferrite transformer.

5. The apparatus of claim 1, wherein the resilient expansion absorption layer is formed of closed-cell foam.

6. The apparatus of claim 1, wherein the resilient expansion absorption layer has a thickness on the order of 2-4 millimeters.

7. The apparatus of claim 1, wherein the equipment box is a die-cast metal box.

8. The apparatus of claim 1, wherein the power module is a DC/DC converter.

9. The apparatus of claim 1, wherein the power module is a DC/AC inverter.

10. The apparatus of claim 1, wherein the power module is an AC/DC inverter.

11. The apparatus of claim 1, further comprising a photovoltaic (PV) module, coupled to the power module, for providing a DC power to the power module.

12. A method for reducing pressure effects on an encapsulated device, comprising:
potting an electronic device to produce a potted electronic device;
disposing the potted electronic device within an equipment module housing; and
disposing a resilient expansion absorption layer between at least a portion of the potted electronic device and at least a portion of the equipment module housing to produce an equipment box assembly.

13. The method of claim 12, wherein the electronic device is a printed circuit board.

14. The method of claim 12, wherein the electronic device comprises at least one electronic component.

15. The method of claim 14, wherein the at least one electronic component is a ferrite transformer.

16. The method of claim 12, wherein the resilient expansion absorption layer is formed of closed-cell foam.

17. The method of claim 12, wherein the resilient expansion absorption layer has a thickness on the order of 2-4 millimeters.

18. The method of claim 12, wherein the equipment box is a die-cast metal box.

19. The method of claim 12, further comprising disposing the equipment box assembly within a power module.

20. The method of claim 19, wherein the power module is an inverter.
